(19) United States
(12) Patent Application Publication
(10) Pub. No.: US 2024/0395968 A1
(43) Pub. Date: Nov. 28, 2024

(54) TILED DISPLAY DEVICE AND DISPLAY DEVICE

(71) Applicant: Samsung Display Co., LTD., Yongin-si (KR)

(72) Inventors: Jong Moo HUH, Yongin-si (KR); Byoung Yong KIM, Yongin-si (KR)

(73) Assignee: Samsung Display Co., LTD., Yongin-si (KR)

(21) Appl. No.: 18/392,226

(22) Filed: Dec. 21, 2023

(30) Foreign Application Priority Data
May 24, 2023 (KR) 10-2023-0067057

(51) Int. Cl. H01L 33/08; H01L 25/075; H01L 33/50

(52) U.S. Cl. CPC H01L 33/08; H01L 25/0753; H01L 33/502

(57) ABSTRACT

A tiled display device includes display devices comprising a first display device and a second display device adjacent to each other, each including a display area including a first display area and a second display area. The first display area includes at least a portion of an inner area of the display area, and the second display area includes at least a portion of an edge area of the display area. Each of the display devices includes inner sub-pixels disposed on a base layer in the first display area, and edge sub-pixels disposed on the base layer in the second display area. The edge sub-pixels include an inorganic light emitting element comprising an inorganic material, and the inner sub-pixels include a light source different from the inorganic light emitting element.

### CROSS REFERENCE TO RELATED APPLICATION(S)

This application claims priority to and benefits of Korean patent application No. 10-2023-0067057 under 35 U.S.C. § 119, filed on May 24, 2023, in the Korean Intellectual Property Office (KIPO), the entire contents of which are incorporated herein by reference.

### BACKGROUND

### 1. Technical Field

The disclosure relates to a tiled display device and a display device.

### 2. Description of the Related Art

In recent years, as interest in information display is increasing, research and development for a display device are continuously being conducted.

### SUMMARY

An aspect of the disclosure is to provide a tiled display device and a display device with improved external visibility and improved process productivity.

According to an embodiment of the disclosure, a tiled display device may include display devices including a first display device and a second display device adjacent to each other, each including a display area including a first display area and a second display area. The first display area may include at least a portion of an inner area of the display area, and the second display area may include at least a portion of an edge area of the display area. Each of the display devices may include inner sub-pixels disposed on a base layer in the first display area, and edge sub-pixels disposed on the base layer in the second display area. The edge sub-pixels may include an inorganic light emitting element comprising an inorganic material, and the inner sub-pixels may include a light source different from the inorganic light emitting element.

According to an embodiment, the second display area may be disposed between the first display area of the first display device and the first display area of the second display device.

According to an embodiment, the second display area of the first display device may be disposed directly adjacent to the second display area of the second display device.

According to an embodiment, the second display area may entirely surround a periphery of the first display area in a plan view.

According to an embodiment, the inner sub-pixels may include an organic light emitting diode (OLED) or a liquid crystal display (LCD) light source.

According to an embodiment, the edge sub-pixels may further include a light transmission layer disposed on the inorganic light emitting element.

According to an embodiment, the inner sub-pixels may be spaced apart from each other by a first distance. One of the inner sub-pixels most adjacent to the second display area and one of the edge sub-pixels most adjacent to the first display area may be spaced apart from each other by a second distance. The first distance and the second distance may be equal.

According to an embodiment, the edge sub-pixels may be spaced apart from each other by a third distance. The first distance and the third distance may be equal.

According to an embodiment, one of the edge sub-pixels of the first display device most adjacent to the second display device and one of the edge sub-pixels of the second display device most adjacent to the first display device may be spaced apart from each other by a fourth distance. The first distance and the fourth distance may be equal.

According to an embodiment, each of the display devices may further include a color conversion layer disposed on the inorganic light emitting element and the light source different from the inorganic light emitting clement and comprising a quantum-dot.

According to an embodiment, each of the display devices may further include an upper substrate disposed on the color conversion layer.

According to an embodiment, the inorganic light emitting element may include an N-type semiconductor layer, a P-type semiconductor layer, an active layer disposed between the N-type semiconductor layer and the P-type semiconductor layer, and an element color conversion layer including a quantum-dot. The N-type semiconductor layer may include an accommodating area in which at least a portion of the N-type semiconductor layer is removed. The element color conversion layer may be disposed in the accommodating area.

According to an embodiment of the disclosure, a display device may include an inorganic light emitting element disposed on a base layer and comprising an N-type semiconductor layer, a P-type semiconductor layer, an active layer disposed between the N-type semiconductor layer and the P-type semiconductor layer, and an element color conversion layer comprising a quantum-dot. The N-type semiconductor layer may include an accommodating area in which at least a portion of the N-type semiconductor layer is removed. The element color conversion layer may be disposed in the accommodating area.

According to an embodiment, the inorganic light emitting element may be a red light emitting element or a green light emitting element.

According to an embodiment, the inorganic light emitting element may include a passivation layer passivating the element color conversion layer. The inorganic light emitting element may have an integrated structure including the quantum-dot.

According to an embodiment of the disclosure, a tiled display device and a display device with improved external visibility and improved process productivity may be provided.

### BRIEF DESCRIPTION OF THE DRAWINGS

The above and other features of the disclosure will become more apparent by describing in further detail embodiments thereof with reference to the accompanying drawings, in which:

FIGS. 1 to 3 are plan views illustrating a tiled display device according to an embodiment;

FIGS. 4 to 7 are schematic cross-sectional views illustrating a tiled display device according to an embodiment;

FIG. 8 is a schematic cross-sectional view illustrating a structure of a display layer in a first display area; and

FIG. 9 is a schematic cross-sectional view illustrating the structure of the display layer in a second display area.

### DETAILED DESCRIPTION OF THE EMBODIMENT

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure comprises all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions comprise plural expressions unless the context clearly dictates otherwise.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure relates to a display device. Hereinafter, a tiled display device and a display device according to an embodiment are described with reference to the accompanying drawings.

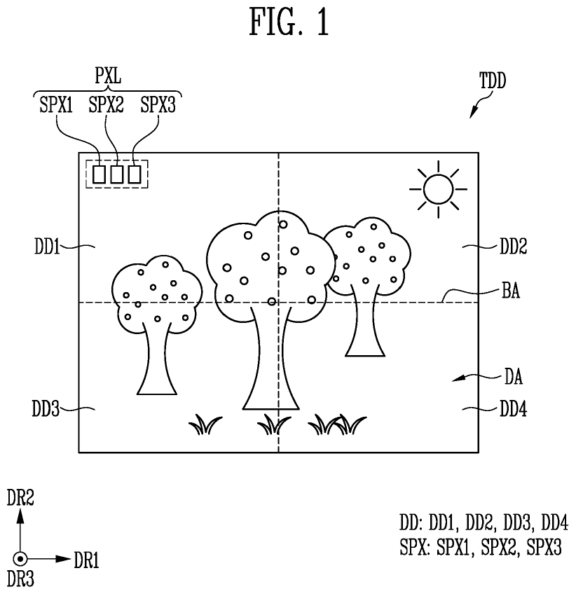

FIGS. 1 to 3 are plan views illustrating a tiled display device according to an embodiment.

A tiled display device TDD may be configured to provide visual information to a user. The tiled display device TDD may provide (or emit) light in a display direction (for example, in a third direction DR3) of the tiled display device TDD.

The tiled display device TDD may be provided by combining multiple display devices DD. According to an embodiment, the tiled display device TDD may have a large screen by combining the display devices DD, and thus may be used in a field requiring a wide display surface such as outdoor advertising.

The display devices DD comprised in the tiled display device TDD may comprise first to fourth display devices DDI to DD4. According to an embodiment, the tiled display device TDD may comprise four display devices, but the number of display devices forming (or configuring) the tiled display device TDD is not limited to a specific example. Hereinafter, for convenience of description, the disclosure is described based on an embodiment comprising four display devices DD1, DD2, DD3, and DD4. A technical feature described based on the display device DD may be commonly applied to each of the first to fourth display devices DD1 to DD4.

The tiled display device TDD may comprise a pixel PXL, a display area DA, and a combining area BA.

Light may be output in the display area DA. The pixel PXL may be disposed in the display area DA. The display area DA may be formed on a surface of the tiled display device TDD, but the is not limited thereto, and may also be formed on a side surface and/or a rear surface of the tiled display device TDD. In the specification, a disclosure is described based on an embodiment in which the display area DA is formed on a surface of the tiled display device TDD.

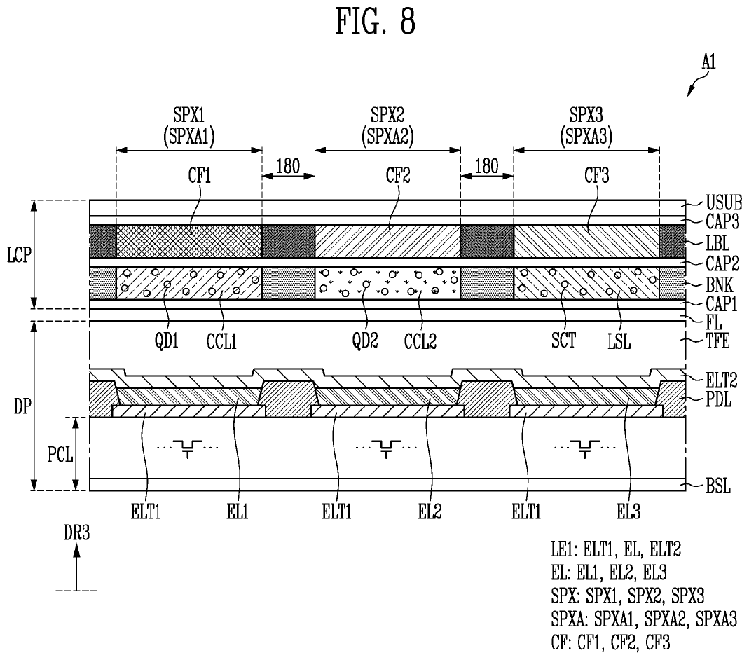

The pixel PXL may be disposed in the display area DA. The pixel PXL may comprise a sub-pixel SPX comprising a first sub-pixel SPX1, a second sub-pixel SPX2, and a third sub-pixel SPX3. The sub-pixels SPX may be disposed (or formed) on a base layer BSL (refer to FIG. 8). Each of the first to third sub-pixels SPX1, SPX2, and SPX3 may output light of a different color and form one pixel unit.

According to an embodiment, light of a first color (for example, red) may be output from the first sub-pixel SPX1, light of a second color (for example, green) may be output from the second sub-pixel SPX2, and light of a third color (for example, blue) may be output from the third sub-pixel SPX3.

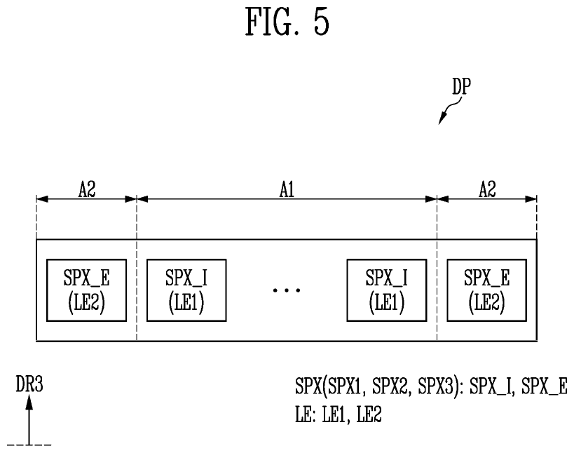

The sub-pixel SPX may comprise a light source. According to an embodiment, at least a portion of the sub-pixels SPX may comprise a first light emitting element LEI (refer to FIG. 5), and at least another portion of the sub-pixels SPX may comprise a second light emitting elements LE2 (refer to FIG. 5). According to an embodiment, by changing a type of the light emitting elements LE1 and LE2 comprised in the sub-pixels SPX for each area, visibility and process may be improved. Details regarding this are described below.

The display area DA may comprise a first display area A1 and a second display area A2. For example, each of the display devices DD may comprise the first display area Al and the second display area A2.

The first display area A1 may comprise at least a portion of an inner area of the display area DA. For example, an internal sub-pixel SPX_I (refer to FIG. 5) may be disposed in the first display area A1. The first display area Al may be an area inside the display area DA and may be an area where an image displayed inside the display device DD is emitted.

The second display area A2 may comprise at least a portion of an edge area of the display area DA. For example, an edge sub-pixel SPX_E (refer to FIG. 5) may be disposed in the second display area A2. The second display area A2 may be an edge area of the display area DA, and may be an area from which an image displayed at each edge of the display device DD is emitted.

The first display area A1 and the second display area A2 may be disposed adjacent to each other. For example, at least a portion of the second display area A2 may be disposed between the first display area A1 of the first display device DDI and the first display area A1 of the second display device DD2. At least a portion of the second display area A2 may be disposed between the first display area A1 of the first display device DDI and the first display area A1 of the third display device DD3. At least a portion of the second display area A2 may be disposed between the first display area A1 of the second display device DD2 and the first display area Al of the third display device DD3. At least a portion of the second display area A2 may be disposed between the first display area A1 of the third display device DD3 and the first display area Al of the fourth display device DD4. Accordingly, the second display area A2 may be formed adjacent to the combining area BA between display devices DD adjacent to each other.

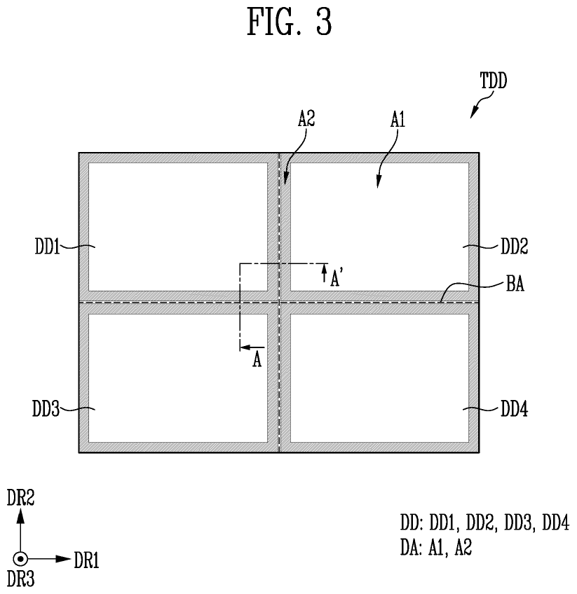

According to an embodiment, the second display area A2 may be formed adjacent to the combining area BA, and may be entirely disposed at the outermost edge of each of the display devices DD (refer to FIG. 3).

For example, the second display area A2 may be disposed along outer lines of the first display device DD1. The second display area A2 may entirely surround an edge of the first display area Al of the first display device DD1. The second display area A2 may be disposed along outer lines of the second display device DD2. The second display area A2 may entirely surround an edge of the first display area Al of the second display device DD2. The second display area A2 may be disposed along outer lines of the third display device DD3. The second display area A2 may entirely surround an edge of the first display area Al of the third display device DD3. The second display area A2 may be disposed along outer lines of the fourth display device DD4. The second display area A2 may entirely surround an edge of the first display area Al of the fourth display device DD4. According to an embodiment, the tiled display device TDD may comprise two or more first display areas Al of which all of each peripheries are surrounded by the second display area A2.

The second display area A2 of one of the display devices DD may be disposed adjacent to (e.g., directly adjacent to) the second display area A2 of another adjacent display device DD. For example, the second display area A2 of the first display device DDI may be disposed adjacent to (e.g., directly adjacent to) the second display area A2 of the second display device DD2 and the third display device DD3. The second display area A2 of the fourth display device DD4 may be disposed adjacent to (e.g., directly adjacent to) the second display area A2 of the second display device DD2 and the third display device DD3.

According to an embodiment, although not shown in the drawing, the tiled display device TDD may further comprise a non-display area in which the pixel PXL is not disposed. For example, the non-display area may be disposed on at least a portion of the outermost edge of the tiled display device TDD. However, the disclosure is not limited thereto, and the non-display area may not be formed.

The combining area BA may be an area between the display devices DD comprised in the tiled display device TDD. According to an embodiment, the display devices DD may be coupled to each other with the combining area BA interposed the display devices DD. For example, various adhesive members may be provided in the combining area BA. However, a method of combining the display devices DD is not particularly limited.

According to an embodiment, at least a portion of the combining area BA may be disposed between the first display device DDI and the second display device DD2. For example, the combining area BA may comprise a first combining area disposed between the first display device DD1 and the second display device DD2, a second combining area disposed between the first display device DD1 and the third display device DD3, a third combining area disposed between the second display device DD2 and the fourth display device DD4, and a fourth combining area disposed between the third display device DD3 and the fourth display device DD4.

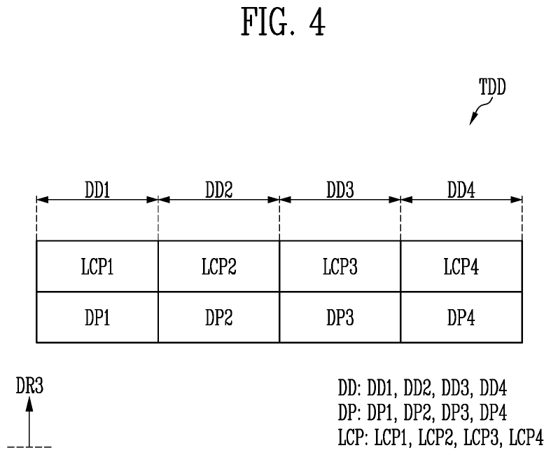

Hereinafter, a cross-sectional structure of a tiled display device TDD according to an embodiment is described with reference to FIGS. 4 to 7. A content that may overlap the above-described content is briefly described or is not repeated.

FIGS. 4 to 7 are schematic cross-sectional views illustrating a tiled display device according to an embodiment.

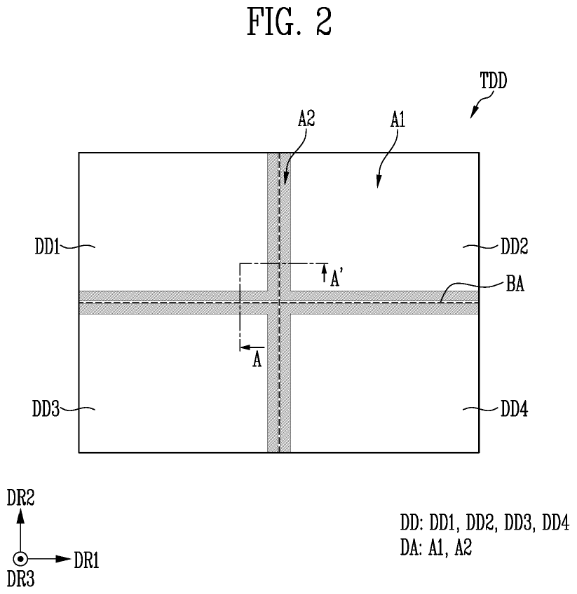

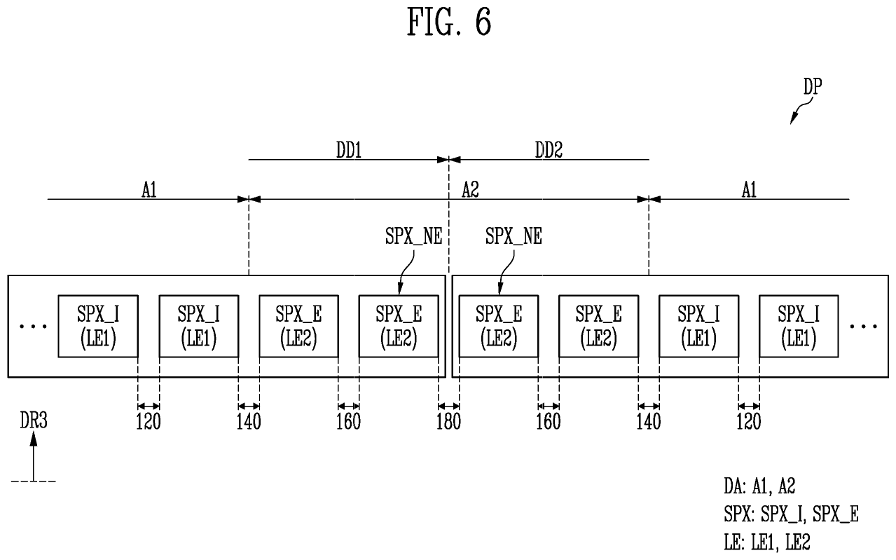

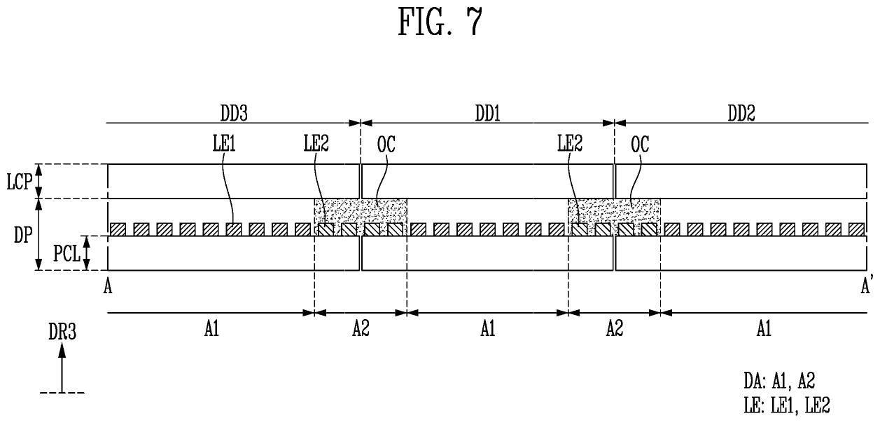

FIG. 4 schematically shows a cross-sectional structure of the first to fourth display devices DD1 to DD4. FIG. 5 schematically shows a display layer DP of each of the display devices DD. FIG. 6 schematically shows a technical feature related to a separation distance between sub-pixels SPX adjacent to each other. FIG. 7 schematically shows a technical feature that each display device DD comprises different light sources for each area. FIG. 7 is a schematic cross-sectional view taken along-line A˜A' of FIGS. 2 and 3.

Referring to FIGS. 4 to 7, each of the display devices DD may comprise a display layer DP and a light control layer LCP. The display layer DP and the light control layer LCP may be disposed adjacent to each other in a thickness direction (for example, the third direction DR3) of the base layer BSL (refer to FIG. 8). Light emitted from the display layer DP may pass through the light control layer LCP and may be emitted to an outside. According to an embodiment, the display layer DP and the light control layer LCP may be combined with each other. For example, a filling layer FL (refer to FIG. 8) may be interposed between the display layer DP and the light control layer LCP. A method of combining the display layer DP and the light control layer LCP is not particularly limited.

The display layer DP may comprise a first display layer DPI comprised in the first display device DD1, a second display layer DP2 comprised in the second display device DD2, a third display layer DP3 comprised in the third display device DD3, and a fourth display layer DP4 comprised in the fourth display device DD4. The first to fourth display layers DPI to DP4 may be disposed adjacent to each other with the combining area BA interposed between the first to fourth display layers DPI to DP4.

The display layer DP may be a layer comprising a light source (for example, a light emitting element LE). For example, the display layer DP may comprise a first light emitting element LE1. The display layer DP may comprise a second light emitting element LE2. According to an embodiment, a portion of the display layer DP may comprise color conversion layers CCL1 and CCL2 (refer to FIG. 8). According to an embodiment, the display layer DP may comprise a base layer BSL and a pixel circuit layer PCL comprising a pixel circuit for driving the light emitting elements LE. The first light emitting elements LEI and the second light emitting elements LE2 may be disposed on the pixel circuit layer PCL.

According to an embodiment, the base layer BSL may be a base substrate or a base member for supporting the display devices DD. The base layer BSL may be a rigid substrate of a glass material. According to another embodiment, the base layer may be a flexible substrate of which bending, folding, rolling, or the like is possible. The base layer BSL may comprise an insulating material such as a polymer resin such as polyimide. However, the disclosure is not particularly limited thereto. The pixel circuit may comprise a thin film transistor. The pixel circuit may comprise a driving transistor. The pixel circuit may be electrically connected to the light emitting elements LE to provide an electrical signal for the light emitting elements LE to emit light.

According to an embodiment, the display layer DP may comprise different light sources in the respective first display area Al and second display area A2. The display layer DP may comprise an internal sub-pixel SPX_I disposed (or formed) in the first display area Al. The display layer DP may comprise an edge sub-pixel SPX_E disposed (or formed) in the second display area A2. The inner sub-pixel SPX_I may be one or more of the sub-pixels SPX, and the edge sub-pixel SPX_E may be one or more of the sub-pixels SPX. The inner sub-pixel SPX_I and the edge sub-pixel SPX_E may comprise different light sources.

For example, the internal sub-pixel SPX_I may comprise a light source other than a light emitting diode comprising an inorganic material in the first display area Al. According to an embodiment, the internal sub-pixel SPX_I may comprise a first light emitting element LEI comprising an organic material. The first light emitting element LEI may comprise organic light emitting diode (OLED). According to another embodiment, the internal sub-pixel SPX_I may comprise a liquid crystal display (LCD) light source. Hereinafter, for convenience of description, the disclosure is described based on an embodiment in which the internal sub-pixel SPX_I comprises the OLED.

For example, the edge sub-pixel SPX may comprise the second light emitting element LE2 as a light source comprising an inorganic material in the second display area A2. The second light emitting element LE2 may comprise semiconductor layers comprising an inorganic material. According to an embodiment, the second light emitting element LE2 may be a micro LED. However, the disclosure is not limited thereto, and the second light emitting element LE2 may be a nano LED.

According to an embodiment, the display layer DP may comprise a light transmission layer OC disposed on the second light emitting elements LE2. The light transmission layer OC may be disposed in the second display area A2 to transmit light provided by the second light emitting elements LE2. The light transmission layer OC may be an overcoat layer.

Since it is difficult to form a sub-pixel structure in edge areas between display panels of a conventional tiled display device, a black matrix layer or the like is disposed in the edge areas so that an internal structure is not visible, and visibility of the conventional tiled display device may be impaired. However, in the tiled display device TDD according to an embodiment, the second light emitting element LE2 and the light transmission layer OC that transmits light provided therefrom are disposed in the edge area, thereby reducing a risk that visibility is impaired.

According to an embodiment, the light transmission layer OC may comprise an organic material such as an acrylic resin, an epoxy resin, a phenolic resin, a polyamide resin, a polyimide resin, a polyester resin, a polyphenylenesulfide resin, or benzocyclobutene (BCB). However, the disclosure is not necessarily limited thereto, and the light transmission layer OC may comprise various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

According to an embodiment, the internal sub-pixels SPX_I may be disposed in the first display area A1 to provide light, and the edge sub-pixels SPX_E may be disposed in the second display area A2 to provide light. According to an embodiment, the inner sub-pixel SPX_I and the edge sub-pixel SPX_E may be disposed adjacent to each other in an area where the first display area Al and the second display area A2 are disposed adjacent to each other.

According to an embodiment, the sub-pixels SPX may be spaced apart from each other generally evenly in the first display area Al, the second display area A2, and an area where the first display area Al and the second display area A2 are adjacent to each other. Description will focus on the first display device DDI and the second display device DD2 among the display devices DD for convenience of description.

First to fourth distances 120, 140, 160, and 180 defined in the specification may be defined based on a direction in which a plane on which the base layer BSL is disposed extends (for example, the first direction DR1 or the second direction DR2), and, for example, may be defined based on the shortest distance in which the sub-pixels SPX are spaced apart from each other in a plan view.

In the first display area Al of the first display device DDI and the second display device DD2, the internal sub-pixels SPX_I may be spaced apart from each other by the first distance 120.

In the second display area A2 of the first display device DDI and the second display device DD2, the edge sub-pixels SPX_E may be spaced apart from each other by the third distance 160. For example, a sub-pixel most adjacent to the second display area A2 among the inner sub-pixels SPX_I and a sub-pixel most adjacent to the first display area Al among the edge sub-pixels SPX_E may be spaced apart from each other by the second distance 140.

The edge sub-pixel SPX_E and the inner sub-pixel SPX_I may be spaced apart from each other by the second distance 140 in an area where the first display area Al and the second display area A2 of the first display device DDI and the second display device DD2 are adjacent.

A most adjacent edge sub-pixel SPX_NE most adjacent to the second display device DD2 among the edge sub-pixels SPX_E of the first display device DDI and a most adjacent edge sub-pixel SPX_NE most adjacent to the first display device DDI among the edge sub-pixels SPX_E of the second display device DD2 may be spaced apart from each other by the fourth distance 180. The most adjacent edge sub-pixel SPX_NE of each of the display devices DD may be disposed adjacent to (e.g., directly adjacent to) the most adjacent edge sub-pixel SPX_NE of another adjacent display device DD.

According to an embodiment, the first distance 120, the second distance 140, the third distance 160, and the fourth distance 180 may be generally uniform. For example, the first distance 120, the second distance 140, the third distance 160, and the fourth distance 180 may be equal.

Accordingly, in accordance with the tiled display device TDD according to an embodiment, a risk that visibility is impaired in an area where the display devices DD are adjacent each other may be reduced. Experimentally, in case that multiple display panels are connected to each other to manufacture the tiled display device TDD, it may be difficult to dispose the sub-pixels SPX at a relatively high density to have high resolution in the area where the display panels are connected with each other. However, according to an embodiment, the sub-pixels SPX may be formed by using the second light emitting elements LE2 comprising an inorganic material requiring a relatively small space in a periphery of each of the display devices DD forming the tiled display device TDD.

In a technical field of a display device, a level of interest in not only resolution of a device but also an issue of reducing a process cost is high. Typically, a process cost of the second light emitting element LE2 comprising the inorganic material may be higher than a process cost of the first light emitting element LEI (the LCD light source, or the like) comprising the organic material. The second light emitting element LE2 may be disposed at an edge area of the display area DA to form a high-resolution image throughout the tiled display device TDD, and a light source (for example, the first light emitting element LE1) other than the second light emitting element LE2 may be disposed in an inner area of the display area DA, to reduce a process cost.

As a result, the tiled display device TDD according to an embodiment may be manufactured as a device with high display quality while reducing processing cost.

The light control layer LCP may comprise a first light control layer LCP1 comprised in the first display device DD1, a second light control layer LCP2 comprised in the second display device DD2, a third light control layer LCP3 comprised in the third display device DD3, and a fourth light control layer LCP4 comprised in fourth display device DD4. However, the disclosure is not necessarily limited thereto. The light control layer LCP may be integrally formed and may be manufactured to overlap each of the first to fourth display layers DPI to DP4 in a plan view.

The light control layer LCP may be configured to output light of a wavelength band different from the wavelength of light provided from the display layer DP. For example, the light control layer LCP may comprise color conversion layers CCLI and CCL2 configured to change a wavelength of light and/or a color filter CF configured to selectively transmit light of one wavelength band.

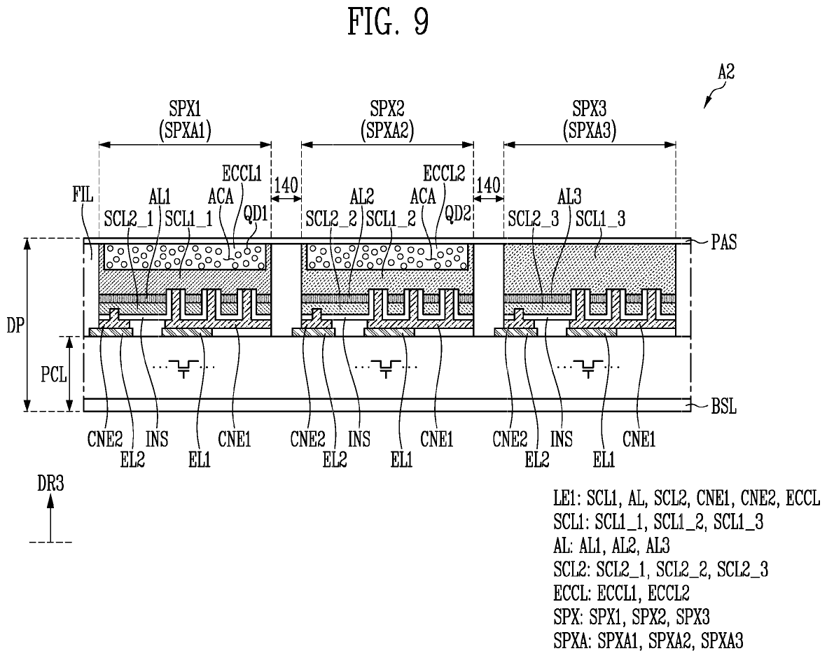

Hereinafter, a structure comprising the light emitting elements LEI and LE2 in the respective first display area Al and second display area A2 is described with reference to FIGS. 8 and 9. A content that may overlap the above-described content is briefly described or is not repeated.

First, a structure of the display layer DP in the first display area Al is described with reference to FIG. 8. FIG. 8 is a schematic cross-sectional view illustrating the structure of the display layer in the first display area. FIG. 8 schematically shows a cross-sectional structure comprising the first light emitting element LEI for forming the internal sub-pixel SPX_I.

According to an embodiment, the sub-pixels SPX and sub-pixel areas SPXA shown in FIG. 8 may correspond to the internal sub-pixel SPX_I.

The sub-pixels SPX may form the sub-pixel areas SPXA. The sub-pixel areas SPXA may be areas where light of different colors is viewed. The sub-pixel areas SPXA may comprise a first sub-pixel area SPXAl where light of a first color is emitted as an area where the first sub-pixel SPX1 is formed, a second sub-pixel area SPXA2 where light of a second color is emitted as an area where the second sub-pixel SPX2 is formed, and a third sub-pixel area SPXA3 where light of a third color is emitted as an area where the third sub-pixel SPX3 is formed.

According to an embodiment, the first light emitting elements LEI may be disposed on the pixel circuit layer PCL. According to an embodiment, the display layer DP may comprise a pixel defining layer PDL and an encapsulation layer TFE.

The first light emitting elements LEI may comprise a first electrode ELT1, a light emitting layer EL, and a second electrode ELT2. The light emitting layer EL may be disposed in an area defined by the pixel defining layer PDL. The pixel defining layer PDL may be disposed adjacent to a periphery of the light emitting layer EL. A surface of the light emitting layer EL may be electrically connected to the first electrode ELT1, and another surface of the light emitting layer EL may be electrically connected to the second electrode ELT2.

According to an embodiment, the light emitting layer EL may comprise a first light emitting layer EL1 comprised in the first sub-pixel SPX1, a second light emitting layer EL2 comprised in the second sub-pixel SPX2, and a third light emitting layer EL3 comprised in the third sub-pixel SPX3. The first light emitting layer EL1 may emit the light of the first color, the second light emitting layer EL2 may emit the light of the second color, and the third light emitting layer EL3 may emit the light of the third color. According to another embodiment, all of the first to third light emitting layers EL1 to EL3 may emit the light of the third color.

The first electrode ELT1 may be an anode electrode for the light emitting layer EL, and the second electrode ELT2 may be a common electrode (or cathode electrode) for the light emitting layer EL. According to an embodiment, the first electrode ELT1 and the second electrode ELT2 may comprise a conductive material. For example, the first electrode ELT1 may comprise a conductive material having a reflective property, and the second electrode ELT2 may comprise a transparent conductive material, but the disclosure is not limited thereto.

The light emitting layer EL may have a multilayer thin film structure comprising a light generation layer. The light emitting layer EL may comprise a hole injection layer for injecting a hole, a hole transport layer having an excellent hole transport property and for increasing a chance of recombination of a hole and an electron by suppressing a movement of an electron that is not combined in the light generation layer, the light generation layer for emitting light by the recombination of the injected electron and hole, a hole blocking layer for suppressing a movement of a hole that is not combined in the light generation layer, an electron transport layer for readily transporting the electron to the light generation layer, and an electron injection layer for injecting the electron. The light emitting layer EL may emit light based on an electrical signal provided from the first electrode ELT1 and the second electrode ELT2.

The pixel defining layer PDL may be disposed on the pixel circuit layer PCL to define a position where the light emitting layer EL is arranged. The pixel defining layer PDL may comprise an organic material. According to an embodiment, the pixel defining layer PDL may comprise at least one of an acrylic resin, an epoxy resin, a phenol resin, a polyamide resin, and a polyimide resin. However, the disclosure is not limited thereto.

The thin film encapsulation layer TFE may be disposed on the first light emitting element LE1. The thin film encapsulation layer TFE may offset a step difference generated by the first light emitting elements LEI and the pixel defining layer PDL. The thin film encapsulation layer TFE may comprise multiple insulating layers covering the first light emitting elements LE1. According to an embodiment, the thin film encapsulation layer TFE may have a structure in which an inorganic layer and an organic layer are alternately stacked each other. According to an embodiment, the encapsulation layer TFE may be a thin film encapsulation layer.

The filling layer FL may be disposed between the display layer DP and the light control layer LCP. The filling layer FL may comprise an organic material such as an acrylic resin, an epoxy resin, a phenolic resin, a polyamide resin, a polyimide resin, a polyester resin, a polyphenylenesulfide resin, or benzocyclobutene (BCB). However, the disclosure is not necessarily limited thereto.

According to an embodiment, the light control layer LCP may comprise a first capping layer CAP1, the color conversion layers CCL1 and CCL2, a scattering layer LSL, a bank BNK, a second capping layer CAP2, a light blocking layer LBL, the color filter CF, a third capping layer CAP3, and an upper substrate USUB.

The first capping layer CAP1 may be disposed on the filling layer FL. The first capping layer CAP1 may cap the first color conversion layer CCL1, the second color conversion layer CCL2, and the scattering layer LSL. The first capping layer CAP1 may comprise an inorganic material, and the material is not particularly limited.

The color conversion layers CCL1 and CCL2 may be configured to change a wavelength of light. The color conversion layers CCL1 and CCL2 and the scattering layer LSL may be disposed on the display layer DP. The color conversion layers CCL1 and CCL2 and the scattering layer LSL may be disposed below the color filters CF. The color conversion layers CC1 and CCL2 and the scattering layer LSL may be disposed between the color filters CF and the display layer DP. The color conversion layers CCL1 and CCL2 and the scattering layer LSL may protrude in a thickness direction (for example, the third direction DR3) of the base layer BSL, and may be disposed (or patterned) in an area surrounded by the bank BNK comprising an organic material.

The first color conversion layer CCL1 may comprise first color conversion particles that convert the light of the third color (for example, blue) into the light of the first color (for example, red). For example, the first color conversion layer CCL1 may comprise multiple first quantum-dots QD1 dispersed in a matrix material such as a base resin. The first quantum-dot QD1 may absorb blue light and emit red light by shifting a wavelength according to an energy transition.

The second color conversion layer CCL2 may comprise second color conversion particles that convert the light of the third color (for example, blue) into the light of the second color (for example, green). For example, the second color conversion layer CCL2 may comprise multiple second quantum-dots QD2 dispersed in a matrix material such as a base resin. The second quantum-dot QD2 may absorb blue light and emit green light by shifting a wavelength according to an energy transition.

In an embodiment, an absorption coefficient of the first quantum-dot QD1 and the second quantum-dot QD2 may be increased by causing blue light having a relatively short wavelength in a visible ray area to be incident to each of the first quantum-dot QD1 and the second quantum-dot QD2. Accordingly, efficiency of light emitted from the first sub-pixel SPX1 and the second sub-pixel SPX2 may be improved and excellent color reproducibility may be secured.

The scattering layer LSL may be provided to efficiently use the light of the third color (or blue). For example, the scattering layer LSL may comprise a scattering body SCT. For example, the scattering body SCT of the scattering layer LSL may comprise at least one of barium sulfate (BaSO₄), calcium carbonate (CaCO₃), titanium oxide (TiO₂), silicon oxide (SiO₂), aluminum oxide (Al₂O₃), zirconium oxide (ZrO₂), and zinc oxide (ZnO). For example, the scattering body SCT may be disposed in the third sub-pixel SPX3, and may be selectively comprised in the first color conversion layer CCL1 or the second color conversion layer CCL2. According to an embodiment, the scattering layer LSL configured of a transparent polymer may be provided by omitting the scattering body SCT.

According to an embodiment, the first distance 120 defined as a separation distance between the internal sub-pixels SPX_I may be a separation distance between the sub-pixel areas SPXA. For example, the first distance 120 may be a width of the light blocking layer LBL in a plan view, and may be a width of the bank BNK according to an embodiment.

The second capping layer CAP2 may be disposed on the color conversion layers CCLI and CCL2 and the scattering layer LSL. The second capping layer CAP2 may cap the first color conversion layer CCL1, the second color conversion layer CCL2, and the scattering layer LSL. The second capping layer CAP2 may comprise an inorganic material, and the material is not particularly limited.

The color filter CF may comprise an organic material such as a colorant and may be configured to selectively transmit light of a color. The color filter CF may be disposed on the color conversion layers CCLI and CCL2 and the scattering layer LSL.

The color filter CFI may comprise a first color filter CF1, a second color filter CF2, and a third color filter CF3.

The first color filter CFI may be a color filter for forming the first sub-pixel SPX1 and may overlap the first sub-pixel area SPXAl in a plan view. The first color filter CFI may selectively transmit the light of the first color. The first color filter CFI may be a red color filter and may comprise a red color filter material.

The second color filter CF2 may be a color filter for forming the second sub-pixel SPX2 and may overlap the second sub-pixel area SPXA2 in a plan view. The second color filter CF2 may selectively transmit the light of the second color. The second color filter CF2 may be a green color filter and may comprise a green color filter material.

The third color filter CF3 may be a color filter for forming the third sub-pixel SPX3 and may overlap the third sub-pixel area SPXA3 in a plan view. The third color filter CF3 may selectively transmit the light of the third color. The third color filter CF3 may be a blue color filter and may comprise a blue color filter material.

The light blocking layer LBL may be disposed between the sub-pixel areas SPXA. The light blocking layer BM may divide sub-pixel areas SPXA adjacent to each other. The light blocking layer LBL may overlap the bank BNK and the pixel defining layer PDL in a plan view.

The light blocking layer LBL may comprise a light blocking material such as a black matrix, and according to an embodiment, the first to third color filters CFI to CF3 may overlap in a plan view to form the light blocking layer LBL.

The third capping layer CAP3 may be disposed on the color filter CF. The third capping layer CAP3 may cap the color filter CF. The third capping layer CAP3 may comprise an inorganic material, and the material is not particularly limited.

The upper substrate USUB may be disposed on the third capping layer CAP3. The upper substrate USUB may comprise a material having light transmission. The upper substrate USUB may be a rigid substrate or a flexible substrate. According to an embodiment, the upper substrate USUB may be a window member or an encapsulation substrate.

Referring to FIG. 9, a structure of the display layer DP in the second display area A2 is described. FIG. 9 is a schematic cross-sectional view illustrating the structure of the display layer in the second display area. FIG. 9 schematically shows a cross-sectional structure comprising the second light emitting element LE2 for forming the edge sub-pixel SPX_E.

According to an embodiment, the sub-pixels SPX and the sub-pixel areas SPXA shown in FIG. 9 may correspond to the edge sub-pixel SPX_E.

The display layer DP may comprise connection electrodes ELI and EL2 disposed on the pixel circuit layer PCL, the second light emitting elements LE2 electrically connected to the connection electrodes ELI and EL2, an intermediate layer FIL, and a passivation layer PAS.

A first connection electrode ELI and a second connection electrode EL2 may be configured to supply a cathode signal and an anode signal to the second light emitting element LE2. For example, the first connection electrode ELI may be electrically connected to a first clement electrode CNE1 and may be electrically connected to a pixel circuit (for example, a driving transistor) of the pixel circuit layer PCL. The second connection electrode EL2 may be electrically connected to a second element electrode CNE2 and may be electrically connected to a power line formed on the pixel circuit layer PCL or another layer.

According to an embodiment, the second light emitting elements LE2 disposed in the second display area A2 may be light emitting diodes comprising an inorganic material. According to an embodiment, the second light emitting element LE2 may comprise an N-type semiconductor layer SCL1, a P-type semiconductor layer SCL2, and an active layer AL. The second light emitting element LE2 may further comprise the first element electrode CNE1, the second element electrode CNE2, and an insulating layer INS. According to an embodiment, a portion of the second light emitting elements LE2 may comprise an element color conversion layer ECCL.

The N-type semiconductor layer SCL1 may be disposed on the active layer AL. The N-type semiconductor layer SCL1 may comprise an N-type semiconductor. For example, the N-type semiconductor layer SCL1 may comprise at least one of InAlGaN, GaN, AlGaN, InGaN, AIN, and InN, and a first conductivity type dopant such as Si, Ge, and Sn may be doped. However, the disclosure is not limited thereto.

The N-type semiconductor layer SCL1 may comprise a first N-type semiconductor layer SCL1-1 comprised in the second light emitting element LE2 for forming the first sub-pixel SPX1, a second N-type semiconductor layer SCL1-2 comprised in the second light emitting element LE2 for forming the second sub-pixel SPX2, and a third N-type semiconductor layer SCL1-3 comprised in the second light emitting element LE2 for forming the third sub-pixel SPX3.

The active layer AL may be disposed between the N-type semiconductor layer SCL1 and the P-type semiconductor layer SCL2. The active layer AL may comprise a single-quantum well or multi-quantum well structure. A position of the active layer AL is not limited.

The active layer AL may comprise a first active layer ALI comprised in the second light emitting element LE2 for forming the first sub-pixel SPX1, a second active layer AL2 comprised in the second light emitting element LE2 for forming the second sub-pixel SPX2, and a third active layer AL3 comprised in the second light emitting element LE2 for forming the third sub-pixel SPX3.

The P-type semiconductor layer SCL2 may be disposed on the active layer AL. The P-type semiconductor layer SCL2 may comprise a P-type semiconductor. For example, the P-type semiconductor layer SCL2 may comprise at least one of InAlGaN, GaN, AlGaN, InGaN, AIN, and InN, and a second conductivity type dopant such as Ga, B, and Mg may be doped. However, the disclosure is not limited thereto.

The P-type semiconductor layer SCL2 may comprise a first P-type semiconductor layer SCL2-1 comprised in the second light emitting element LE2 for forming the first sub-pixel SPX1, a second P-type semiconductor layer SCL2-2 comprised in the second light emitting element LE2 for forming the second sub-pixel SPX2, and a third P-type semiconductor layer SCL2-3 comprised in the second light emitting element LE2 for forming the third sub-pixel SPX3.

The first element electrode CNE1 may be electrically connected to the first connection electrode ELI and the N-type semiconductor layer SCL1. The first element electrode CNE1 may supply the cathode signal for emitting light together with the second light emitting element LE2.

The second element electrode CNE2 may be electrically connected to the second connection electrode EL2 and the P-type semiconductor layer SCL2. The second element electrode CNE2 may supply the anode signal for emitting light together with the second light emitting element LE2.

In case that a voltage equal to or greater than a threshold voltage is applied to the first element electrode CNE1 and the second element electrode CNE2 of the second light emitting element LE2, an electron-hole pair may recombine in the active layer AL, and the second light emitting elements LE2 may emit light. The light emitted from the second light emitting elements LE2 may be externally emitted through each of the sub-pixel areas SPXA.

According to an embodiment, the second light emitting element LE2 of the first sub-pixel SPX1 and the second light emitting element LE2 of the second sub-pixel SPX2 may comprise the element color conversion layer ECCL. According to an embodiment, the second light emitting element LE2 comprising the element color conversion layer ECCL may be an inorganic light emitting element and may be a red light emitting element or a green light emitting element.

The element color conversion layer ECCL may comprise a first element color conversion layer ECCL1 comprised in the second light emitting element LE2 of the first sub-pixel SPX1 and a second element color conversion layer ECCL2 comprised in the second light emitting element LE2 of the second sub-pixel SPX2.

The first element color conversion layer ECCL1 may comprise a material corresponding to (or substantially a same material) the first color conversion layer CCLI described above with reference to FIG. 8. For example, the first element color conversion layer ECCL1 may comprise the first quantum-dot QD1.

The second element color conversion layer ECCL2 may comprise a material corresponding to (or substantially a same material) the second color conversion layer CCL2 described above with reference to FIG. 8. For example, the second element color conversion layer ECCL2 may comprise the second quantum-dot QD2.

According to an embodiment, the element color conversion layer ECCL may comprise an accommodating area ACA formed by (or comprised in) the N-type semiconductor layer SCL1 of the second light emitting element LE2. For example, the second light emitting element LE2 of the first sub-pixel SPX1 and the second sub-pixel SPX2 may comprise the accommodating area ACA, and the element color conversion layer ECCL may be disposed in the accommodating area ACA. The accommodating area ACA may be a space defined by the N-type semiconductor layer SCL1, and may be formed by removing (or etching) at least a portion of the N-type semiconductor layer SCL1. The accommodating area ACA may be a structure for trapping the first and second quantum-dots QD1 and QD2.

Accordingly, the second light emitting element LE2 may have an integrated structure in which the first and second quantum-dots QD1 and QD2 are formed in an element structure, and color reproducibility of the second light emitting element LE2 may be further improved, and an additional structure for disposing the first and second quantum-dots QD1 and QD2 may not be required. Thus, configurations may be efficiently disposed in a relatively narrow area.

For example, in case that each of the display devices DD is manufactured to manufacture the tiled display device TDD, securing a sufficient space in an edge area of the display devices DD may be difficult. In case that each of the display devices DD has a light emitting structure comprising the first and second quantum-dots QD1 and QD2, an additional structure for disposing the first and second quantum-dots QD1 and QD2 may be difficult to be formed in the edge area of each of the display devices DD. Accordingly, since properly forming a separate pixel PXL in the edge area is difficult, a concern that visibility of the tiled display device TDD may ultimately be impaired may occur. However, as described above, an area where the first and second quantum-dots QD1 and QD2 may be accommodated may be formed in at least a portion of the second light emitting elements LE2 disposed in the edge area of the display devices DD. Therefore, a light emitting structure with improved color quality may be provided by forming the first and second quantum-dots QD1 and QD2 without consuming an excessive space.

According to an embodiment, the second light emitting element LE2 of the third sub-pixel SPX3 may not comprise the first and second quantum-dots QDI and QD2. However, the disclosure is not necessarily limited thereto. The second light emitting element LE2 of the third sub-pixel SPX3 may also comprise an accommodating area, and thus a material corresponding to the scattering layer LSL may be disposed in the accommodating area.

The insulating layer INS may be disposed on the N-type semiconductor layer SCL1, the P-type semiconductor layer SCL2, and the active layer AL. The insulating layer INS may be disposed between the N-type semiconductor layer SCL1, the P-type semiconductor layer SCL2, and the active layer AL, and the connection electrodes CNE1 and CNE2, and may comprise an inorganic material. For example, the insulating layer INS may comprise at least one of silicon nitride (SiNₓ), silicon oxide (SiOₓ), silicon oxynitride (SiOₓN_{y}), and aluminum oxide (AlOₓ). However, the disclosure is not necessarily limited thereto.

The intermediate layer FIL may be disposed between adjacent second light emitting elements LE2 to ensure structural stability of the second light emitting elements LE2. The intermediate layer FIL may be a filling structure, and may comprise one or more of the materials described above with reference to the filling layer FL.

The passivation layer PAS may be disposed on the second light emitting elements LE2 and the intermediate layer FIL. The passivation layer PAS may cover the second light emitting elements LE2. For example, the passivation layer PAS may package (or seal) the element color conversion layer ECCL. The passivation layer PAS may comprise at least one of silicon nitride (SiNₓ), silicon oxide (SiOₓ), silicon oxynitride (SiOₓN_{y}), and aluminum oxide (AlOₓ). However, the disclosure is not necessarily limited thereto.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A tiled display device comprising:
display devices comprising a first display device and a second display device adjacent to each other, each comprising a display area comprising a first display area and a second display area, wherein
the first display area comprises at least a portion of an inner area of the display area,
the second display area comprises at least a portion of an edge area of the display area,
each of the display devices comprises:
inner sub-pixels disposed on a base layer in the first display area; and
edge sub-pixels disposed on the base layer in the second display area,
the edge sub-pixels comprise an inorganic light emitting element comprising an inorganic material, and
the inner sub-pixels comprise a light source different from the inorganic light emitting element.

2. The tiled display device of claim 1, wherein the second display area is disposed between the first display area of the first display device and the first display area of the second display device.

3. The tiled display device of claim 1, wherein the second display area of the first display device is disposed directly adjacent to the second display area of the second display device.

4. The tiled display device of claim 1, wherein the second display area entirely surrounds a periphery of the first display area in a plan view.

5. The tiled display device of claim 1, wherein the inner sub-pixels comprise an organic light emitting diode (OLED) or a liquid crystal display (LCD) light source.

6. The tiled display device of claim 1, wherein the edge sub-pixels further comprise a light transmission layer disposed on the inorganic light emitting element.

7. The tiled display device of claim 1, wherein
the inner sub-pixels are spaced apart from each other by a first distance,
one of the inner sub-pixels most adjacent to the second display area and one of the edge sub-pixels most adjacent to the first display area are spaced apart from each other by a second distance, and
the first distance and the second distance are equal.

8. The tiled display device of claim 7, wherein
the edge sub-pixels are spaced apart from each other by a third distance, and
the first distance and the third distance are equal.

9. The tiled display device of claim 8, wherein
one of the edge sub-pixels of the first display device most adjacent to the second display device and one of the edge sub-pixels of the second display device most adjacent to the first display device are spaced apart from each other by a fourth distance, and
the first distance and the fourth distance are equal.

10. The tiled display device of claim 1, wherein each of the display devices further comprises a color conversion layer disposed on the inorganic light emitting element and the light source different from the inorganic light emitting element and comprising a quantum-dot.

11. The tiled display device of claim 10, wherein each of the display devices further comprises an upper substrate disposed on the color conversion layer.

12. The tiled display device of claim 1, wherein
the inorganic light emitting element comprises an N-type semiconductor layer, a P-type semiconductor layer, an active layer disposed between the N-type semiconductor layer and the P-type semiconductor layer, and an element color conversion layer comprising a quantum-dot,
the N-type semiconductor layer comprises an accommodating area in which at least a portion of the N-type semiconductor layer is removed, and
the element color conversion layer is disposed in the accommodating area.

13. A display device comprising:
an inorganic light emitting element disposed on a base layer and comprising an N-type semiconductor layer, a P-type semiconductor layer, an active layer disposed between the N-type semiconductor layer and the P-type semiconductor layer, and an element color conversion layer comprising a quantum-dot, wherein
the N-type semiconductor layer comprises an accommodating area in which at least a portion of the N-type semiconductor layer is removed, and
the element color conversion layer is disposed in the accommodating area.

14. The display device of claim 13, wherein the inorganic light emitting element is a red light emitting element or a green light emitting element.

15. The display device of claim 14, wherein
the inorganic light emitting element comprises a passivation layer passivating the element color conversion layer, and
the inorganic light emitting element has an integrated structure comprising the quantum-dot.
